(19) United States
(12) Patent Application Publication
(10) Pub. No.: US 2013/0014800 A1
(43) Pub. Date: Jan. 17, 2013

(54) PHOTOVOLTAIC DEVICE AND METHOD FOR SCRIBING A PHOTOVOLTAIC DEVICE

(71) Applicants: Jason Stephens, Mountain View, CA (US); Kunal Girotra, Mountain View, CA (US); Guleid Hussen, Mountain View, CA (US)

(72) Inventors: Jason Stephens, Mountain View, CA (US); Kunal Girotra, Mountain View, CA (US); Guleid Hussen, Mountain View, CA (US)

(73) Assignee: ThinSilicon Corporation, Mountain View, CA (US)

(21) Appl. No.: 13/182,267

(22) Filed: Jul. 13, 2011

(51) Int. Cl. H01L 31/05; H01L 31/18

(52) U.S. Cl. 136/244; 438/80; 257/E31.054

(57) ABSTRACT

A photovoltaic device includes first and second photovoltaic cells, with each of the first and second photovoltaic cells having a substrate, a lower electrode disposed above the substrate along a deposition axis and that includes a conductive light transmissive layer, one or more semiconductor layers disposed above the substrate along the deposition axis, and an upper electrode disposed above the one or more semiconductor layers along the deposition axis. The semiconductor layers convert incident light into an electric current. The first and second photovoltaic cells are separated by first and second separation gaps. The first separation gap extend along the deposition axis through the lower electrode from the substrate and the second separation gap extends from a deposition surface of the light transmissive layer of the lower electrode and through a remainder of the lower electrode and the one or more semiconductor layers along the deposition axis.

### BACKGROUND

The subject matter herein generally relates to photovoltaic devices and, more particularly, to solar cells.

Photovoltaic devices such as solar cells convert incident light into electricity. The devices may include several solar or photovoltaic cells electrically connected in series with one another. In substrate configuration photovoltaic devices, several photovoltaic cells include semiconductor layers sandwiched between a top electrode and a bottom electrode, which are disposed above a substrate. The top electrode of one solar cell is electrically connected to the bottom electrode of a neighboring solar cell.

Light is incident on the photovoltaic cells through a side of the photovoltaic device that is opposite of the substrate. The light strikes the semiconductor layers, with photons in the light exciting electrons and causing the electrons to separate from atoms in the semiconductor layers. The electrons drift or diffuse through the semiconductor layer stack and are collected at one of the top and bottom electrodes. The collection of the electrons at the top or bottom electrodes generates a voltage difference in the photovoltaic cells. The voltage difference in the photovoltaic cells may be additive across the device. For example, the voltage difference in each of the photovoltaic cells is added together if the photovoltaic cells are connected in series.

In order to fabricate multiple photovoltaic cells that are electrically coupled in series with each other, lasers may be used to scribe or etch lines that electrically separate electrodes of neighboring cells. But, in some known substrate configuration photovoltaic devices, the devices include a reflective bottom electrode that does not permit a laser to be fired through the bottom electrode. For example, a laser may not be able to be fired through the substrate and bottom electrode to scribe a line between and electrically isolate the semiconductor layers and the top electrodes in adjacent photovoltaic cells.

The laser may not be able to be applied to the photovoltaic device from the side that is opposite of the substrate to etch or scribe the semiconductor layer stack and the top electrode. For example, when the laser is incident from above the photovoltaic device and the top electrode, the vaporized semiconductor material that forms when the laser light is absorbed by the semiconductor layers is formed on the top side of the semiconductor layers. A pressure wave is created when the semiconductor material is vaporized by the laser. The pressure wave extends toward the substrate and forces the semiconductor material into, instead of out of, the photovoltaic device. The pressure wave may not force the semiconductor material in a direction where the material can be easily removed from the photovoltaic device.

One known technique to compensate for the lack of explosive removal of the semiconductor material in substrate configuration photovoltaic devices is to heat the semiconductor layers and/or the top electrode for a sufficient time with the laser that the entirety of the semiconductor layers and the top electrode are vaporized. But, heating the semiconductor layers and/or top electrode typically leads to a very large level of excess heat dissipation in the areas surrounding the semiconductor layers and the top electrode. The excess heat dissipation causes the top and/or bottom electrodes to interdiffuse with the semiconductor layers. This intermixing may form an electrical shunt between adjacent photovoltaic cells.

### BRIEF DESCRIPTION OF THE INVENTION

In one embodiment, a photovoltaic device includes first and second photovoltaic cells, with each of the first and second photovoltaic cells having a substrate, a lower electrode disposed above the substrate along a deposition axis and that includes a conductive light transmissive layer, one or more semiconductor layers disposed above the substrate along the deposition axis, and an upper electrode disposed above the one or more semiconductor layers along the deposition axis. The semiconductor layers convert incident light into an electric current. The first and second photovoltaic cells are separated by first and second separation gaps. The first separation gap extends along the deposition axis through the lower electrode from the substrate and the second separation gap extends from a deposition surface of the light transmissive layer of the lower electrode and through a remainder of the lower electrode and the one or more semiconductor layers along the deposition axis.

In another embodiment, a photovoltaic device comprising first and second photovoltaic cells is provided. The photovoltaic device includes a substrate, a conductive light transmissive upper electrode including a light receiving side that is disposed opposite of the substrate along a deposition axis, a conductive lower electrode disposed between the substrate and the upper electrode along the deposition axis, the lower electrode including a conductive light transmissive layer, one or more semiconductor layers disposed between the lower electrode and the upper electrode along the deposition axis, the one or more semiconductor layers converting light that is received through the light receiving side of the upper electrode into an electric current in the first and second photovoltaic cells, a first separation gap extending along the deposition axis through the lower electrode from the substrate to the semiconductor layers, the first separation gap electrically separating portions of the lower electrode in the first and second photovoltaic cells along a lateral axis, and a second separation gap extending along the deposition axis from the conductive light transmissive layer of the lower electrode and through the one or more semiconductor layers to the upper electrode, the second separation gap separating portions of the one or more semiconductor layers in the first and second photovoltaic cells along the lateral axis.

In another embodiment, a method for scribing a photovoltaic device having first and second photovoltaic cells is provided. The method includes providing a substrate and a conductive lower electrode above the substrate along a deposition axis of the photovoltaic device, the lower electrode including a conductive light transmissive layer; directing a first laser light through the substrate to etch a first separation gap in the lower electrode, the first separation gap extending along a lateral axis to electrically separate portions of the lower electrode in the first and second photovoltaic cells; depositing one or more semiconductor layers above the lower electrode along the deposition axis; directing a second laser light through the substrate to etch a second separation gap in the lower electrode and the one or more semiconductor layers, the second separation gap extending along the lateral axis to separate portions of the one or more semiconductor layers in the first and second photovoltaic cells; and depositing a conductive light transmissive upper electrode above the one or more semiconductor layers along the deposition axis, wherein the one or more semiconductor layers convert incident light between the upper and lower electrodes and convert the light into an electric current.

### BRIEF DESCRIPTION OF THE DRAWINGS

FIG. 1 is a perspective view of a substrate configuration photovoltaic device and a detail view of a cross-sectional portion of the photovoltaic device according to one embodiment.

FIG. 2 is a flowchart for a method of manufacturing and scribing a photovoltaic device in accordance with one embodiment.

FIG. 3 illustrates a substrate shown in FIG. 1 in accordance with one embodiment.

FIG. 4 illustrates the substrate shown in FIG. 1 with a lower electrode shown in FIG. 1 deposited above the substrate in accordance with one embodiment.

FIG. 5 illustrates first separation gaps in the lower electrode shown in FIG. 1 in accordance with one embodiment.

FIG. 6 illustrates a semiconductor layer shown in FIG. 1 deposited above the lower electrode and the substrate also shown in FIG. 1 in accordance with one embodiment.

FIG. 7 illustrates second separation gaps that are scribed into the semiconductor layer and partially into the lower electrode shown in FIG. 1 in accordance with one embodiment.

FIG. 8 illustrates an upper electrode shown in FIG. 1 deposited above the semiconductor layer and the lower electrode also shown in FIG. 1 in accordance with one embodiment.

FIG. 9 illustrates third separation gaps that extend through the upper electrode shown in FIG. 1 in accordance with one embodiment.

FIG. 10 illustrates an adhesive shown in FIG. 1 deposited above the upper electrode also shown in FIG. 1 in accordance with one embodiment.

FIG. 11 illustrates a cross-sectional view of the photovoltaic device shown in FIG. 1 after a cover sheet also shown in FIG. 1 is provided in accordance with one embodiment.

### DETAILED DESCRIPTION OF THE INVENTION

The foregoing summary, as well as the following detailed description of certain embodiments of the present invention, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

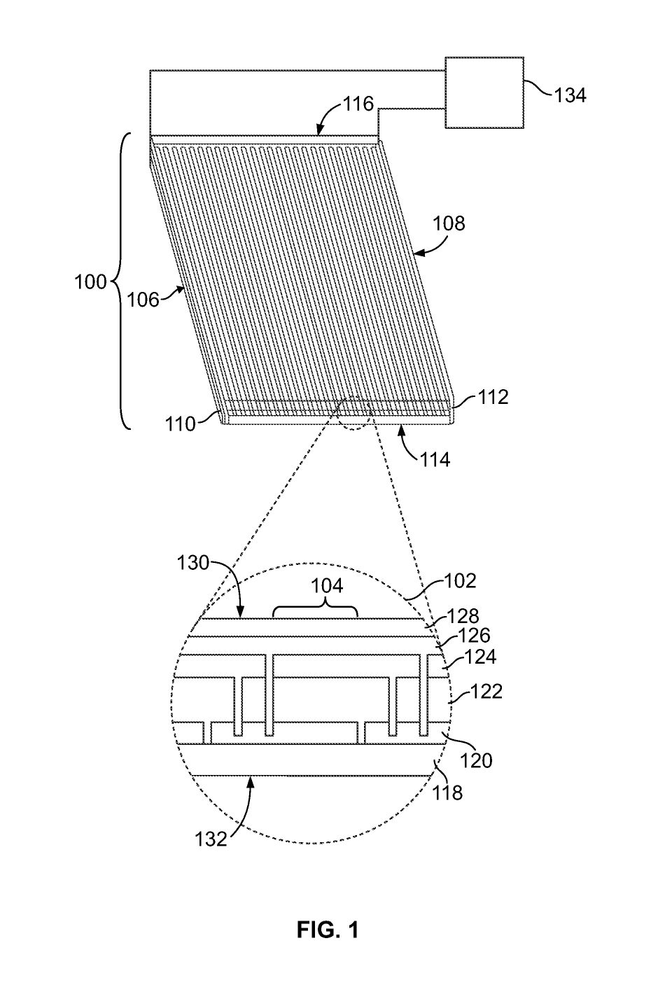

FIG. 1 is a perspective view of a substrate configuration photovoltaic device 100 and a detail view 102 of a cross-sectional portion of the photovoltaic device 100 according to one embodiment. The photovoltaic device 100 may be a solar module that converts incident light into electric current. The photovoltaic device 100 includes a plurality of photovoltaic cells 104 electrically connected in series with one another. In the detail view 102 shown in FIG. 1, only one of the photovoltaic cells 104 is shown. The photovoltaic module 100 may have several additional photovoltaic cells 104 disposed on opposite sides of the photovoltaic cell 104 shown in the detail view 102, such as twenty-five or more serially connected with one another. The photovoltaic cells 104 located along opposite sides 106, 108 of the photovoltaic module 100 can be electrically connected with conductive leads 110, 112. The leads 110, 112 shown in FIG. 1 extend between opposite ends 114, 116 of the photovoltaic module 100. The leads 110, 112 are electrically connected with a circuit 134. The circuit 134 may include a load to which the current generated by the photovoltaic module 100 is applied or a power storage device in which the energy of the current is stored. For example, the circuit 134 may include an electronic device, such as a light, motor, electromechanical device, and the like, or a battery that receives and stores the energy of the current.

In the view shown in FIG. 1, the photovoltaic cells 104 are disposed above a substrate 118. The photovoltaic cells 104 include multiple layers or films that are disposed above the substrate 118. The substrate 118 continuously extends below the other layers and components of the multiple photovoltaic cells 104 in the illustrated embodiment. These layers or films include a lower electrode 120, a semiconductor layer 122, an upper electrode 124, an adhesive 126, and a cover sheet 128. The upper electrode 124 of one photovoltaic cell 104 extends downward through the semiconductor layer 122 to electrically couple with the lower electrode 120 of another neighboring photovoltaic cell 104. The upper electrode 124 of a first photovoltaic cell 104 is electrically coupled with the lower electrode 120 of a second photovoltaic cell 104 to provide a conductive pathway between the neighboring photovoltaic cells 104. The semiconductor layer 122 may include multiple layers or films. For example, the semiconductor layer 122 may include an NIP junction of an n-doped silicon layer deposited on the lower electrode 120, an intrinsic silicon layer deposited on the n-doped layer, and a p-doped silicon layer deposited on the intrinsic layer. Alternatively, the semiconductor layer 122 may include a PIN junction or multiple NIP and/or PIN junctions.

Light is received into the photovoltaic device 100 through a film side 130 of the photovoltaic device 100. The opposite side of the photovoltaic device 100 may be referred to as a substrate side 132. The light passes through the cover sheet 128, adhesive 126, and the upper electrode 124 and into the semiconductor layer 122. At least some of the light is absorbed by the semiconductor layer 122. Some of the light may pass through the semiconductor layer 122 and be reflected back into the semiconductor layer 122 by the lower electrode 120. Photons in the light excite electrons and cause the electrons to separate from atoms in the semiconductor layer 122. The electrons drift or diffuse through the semiconductor layer 122 and are collected at the upper or lower electrodes 124, 120. The collection of the electrons at the upper or lower electrodes 124, 120 generates voltage differences in the photovoltaic cells 104. The voltage differences in the photovoltaic cells 104 may be additive across the photovoltaic device 100. For example, the voltage difference in several of the photovoltaic cells 104 may be added together and increase the total voltage obtained from the photovoltaic device 100. Current flows to the circuit 134 through the connection of the leads 110, 112 to the lower and upper electrodes 120, 124 in the photovoltaic cells 104 located along the sides 106, 108. For example, a first lead 110 may be electrically connected to the upper electrode 124 in the photovoltaic cell 104 that extends along the side 106 while a second lead 112 is electrically connected to the lower electrode 120 in the photovoltaic cell 104 that extends along the opposite side 108.

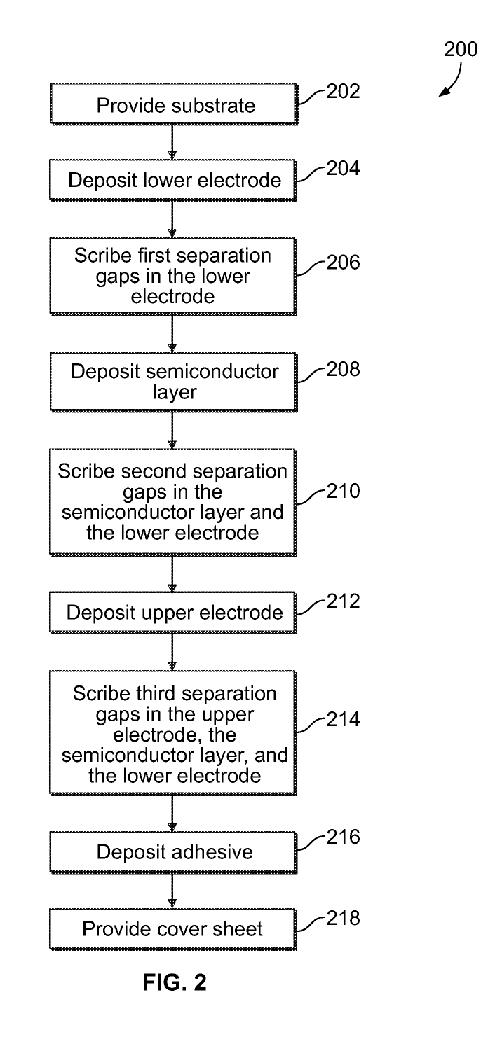

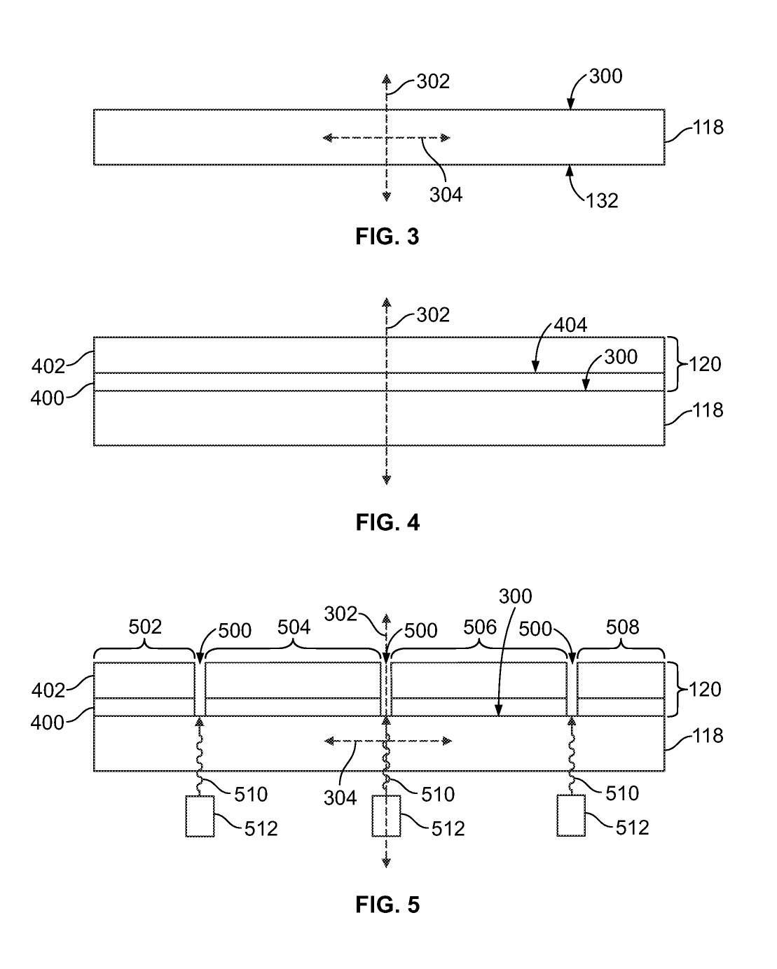

FIG. 2 is a flowchart for a method 200 of manufacturing and scribing a photovoltaic device in accordance with one embodiment. The method 200 may be used to manufacture the photovoltaic device 100 (shown in FIG. 1). FIGS. 3 through 11 illustrate a cross-sectional view of the photovoltaic device 100 following various operations described in connection with the method 200. The method 200 is described in connection with FIGS. 3 through 11.

At 202, the substrate 118 (shown in FIG. 1) is provided. FIG. 3 illustrates the substrate 118 in accordance with one embodiment. The substrate 118 may include or be formed from a non-conducting material such as a glass sheet. The substrate 118 is formed from one or more materials that are transmissive to light. For example, the substrate 118 may be formed from a glass that permits laser light to pass through the substrate 118. The substrate 118 has an upper deposition surface 300 that is oriented opposite of the substrate side 132 of the substrate 118 and the photovoltaic device 100. As shown in FIG. 1, the substrate side 132 is opposite of the film side 130 (shown in FIG. 1) of the photovoltaic device 100 and the deposition surface 300 of the substrate 118 is located between the substrate side 132 of the substrate 118 and the film side 130 of the photovoltaic device 100 along a deposition axis 302.

The deposition axis 302 is oriented along directions in which one or more layers of the photovoltaic device 100 (shown in FIG. 1) are deposited onto lower layers. In the illustrated embodiment, the deposition axis 302 is oriented perpendicular to the deposition surface 300 of the substrate 118. A lateral axis 304 of the photovoltaic device 100 is oriented orthogonal to the deposition axis 302. For example, the lateral axis 304 may be perpendicular to the deposition axis 302 and parallel to the deposition surface 300.

Returning to the discussion of the method 200 shown in FIG. 2, at 204, the lower electrode 120 (shown in FIG. 1) is deposited above the substrate 118 (shown in FIG. 1). FIG. 4 illustrates the substrate 118 with the lower electrode 120 deposited above the substrate 118 in accordance with one embodiment. In the illustrated embodiment, the lower electrode 120 is deposited onto the deposition surface 300 of the substrate 118 such that the lower electrode 120 abuts the substrate 118.

The lower electrode 120 may be formed from two or more layers or films. For example, the lower electrode 120 may include a conductive light transmissive layer 400 and a conductive reflective layer 402. Alternatively, the lower electrode 120 may include a single layer or be formed from more than two layers. In the illustrated embodiment, the conductive light transmissive layer 400 is deposited onto and abuts the deposition surface 300 of the substrate 118 and the conductive reflective layer 402 is deposited onto and abuts an upper deposition surface 404 of the conductive light transmissive layer 400. Alternatively, the conductive light transmissive layer 400 may be part of the substrate 118. For example, the substrate 118 may be purchased or provided with the conductive layer transmissive layer 400 already a part of the substrate 118, such as a transparent conductive oxide (TCO) glass substrate. Once the photovoltaic device 100 (shown in FIG. 1) is assembled, the deposition surface 404 of the conductive light transmissive layer 400 is disposed between the substrate 118 and the film side 130 (shown in FIG. 1) of the photovoltaic device 100 along the deposition axis 302.

The conductive light transmissive layer 400 may be deposited above the substrate 118 along directions that are parallel or approximately parallel to the deposition axis 302. The conductive light transmissive layer 400 includes or is formed from one or more materials that is electrically conductive and that allows light to pass through the layer 400. By way of example only, the conductive light transmissive layer 400 may be a conductive layer that includes or is formed from indium tin oxide (ITO). Alternatively, the conductive light transmissive layer 400 may be deposited as a layer of aluminum doped zinc oxide (Al:ZnO), boron doped zinc oxide (B:ZnO), gallium doped zinc oxide (Ga:ZnO), or another type of zinc oxide (ZnO) that conducts electric current.

The conductive reflective layer 402 is disposed above the conductive light transmissive layer 400 along the deposition axis 302. For example, the conductive reflective layer 402 may be deposited onto the conductive light transmissive layer 400 in directions along the deposition axis 302. The conductive reflective layer 402 is formed from or includes materials that reflect light. For example, at least some of the light that passes through the semiconductor layer 122 (shown in FIG. 1) and strikes the conductive reflective layer 402 may be reflected off of the conductive reflective layer 402 and back into the semiconductor layer 122. The conductive reflective layer 402 may be formed from silver (Ag), aluminum (Al) and/or Nichrome (NiCr).

Returning to the discussion of the method 200 shown in FIG. 2, at 206, first separation gaps 500 are scribed or etched into the lower electrode 120 (shown in FIG. 1). FIG. 5 illustrates the first separation gaps 500 in the lower electrode 120 in accordance with one embodiment. The first separation gaps 500 divide the lower electrode 120 into neighboring sections 502, 504, 506, 508. For example, the first separation gaps 500 spatially separate the sections 502, 504, 506, 508 of the lower electrode 120 from each other to spatially separate and electrically isolate the sections 502, 504, 506, 508 from each other. The sections 502, 504, 506, 508 are laterally separated from each other in directions that are parallel to the lateral axis 304. In one embodiment, each of the sections 502, 504, 506 may provide all or a portion of the lower electrode 120 for a different photovoltaic cell 104 (shown in FIG. 1) of the photovoltaic module 100 (shown in FIG. 1).

The first separation gaps 500 vertically extend through the entirety of the lower electrode 120 in the illustrated embodiment. For example, the first separation gaps 500 may vertically extend from the deposition surface 300 of the substrate 118 through the lower electrode 120 in directions that are parallel to the deposition axis 302. The first separation gaps 500 extend through both the conductive light transmissive layer 400 and the conductive reflective layer 402 to spatially and electrically separate the sections 502, 504, 506, 508 of the lower electrode 120 from each other in directions that are parallel to the lateral axis 304.

The first separation gaps 500 may be etched through the lower electrode 120 by scribing the lower electrode 120 with a focused beam of energy that is directed into the lower electrode 120 through the substrate 118. For example, the first separation gaps 500 may be formed by directing a laser light 510 into the lower electrode 120. In one embodiment, the laser light 510 is referred to as a P1 etch or scribe. The laser light 510 may be directed at the lower electrode 120 through the substrate 118. For example, a laser light source 512 may direct the laser light 510 toward the substrate side 132 of the substrate 118. The substrate 118 may be a light transmissive body that permits the laser light 510 to pass through the substrate 118 and strike the lower electrode 120. The energy of the laser light 510 can heat up and remove portions of the lower electrode 120 to form the first separation gaps 500. Each laser light 510 that is directed into the lower electrode 120 may form one of the first separation gaps 500. Alternatively, the first separation gaps 500 may be formed by exposing the lower electrode to a different focused beam of energy, such as an electron beam, radiation, or some other form of energy. In another embodiment, the first separation gaps 500 may be formed by chemically etching the lower electrode 120 in a direction from above the lower electrode 120.

The wavelength(s) of the laser light 510 that is directed into the lower electrode 120 to form the first separation gaps 500 may be based upon the materials that form the conductive light transmissive layer 400 and the conductive reflective layer 402. For example, in order to form one of the first separation gaps 500, two or more laser lights 510 having different wavelengths may be directed into the lower electrode 120 through the substrate 118. The laser light 510 may include a first laser light 510A having a first wavelength and a second laser light 510B that are directed into the lower electrode 120 through the substrate 118. The first and second laser lights 510A, 510B are not shown in FIG. 5 but may be represented by the reference number 510. The first wavelength of the first laser light 510A may be based on the materials that form the conductive light transmissive layer 400. For example, the first wavelength may be a wavelength of laser light that is absorbed by the conductive light transmissive layer 400 more than one or more other wavelengths of laser light. The absorption of the first laser light 510A by the conductive light transmissive layer 400 causes the first laser light 510A to remove the conductive light transmissive layer 400 and form the first separation gap 500 through the conductive light transmissive layer 400.

The second laser light 510B may have a second wavelength that is different from the first wavelength. The second laser light 510B may be directed into the conductive reflective layer 402 through the substrate 118. The second laser light 510B can be directed into the conductive reflective layer 402 along the same or similar direction that the first laser light 510A was directed into the conductive light transmissive layer 400. The second wavelength of the second laser light 510B may be absorbed by the conductive reflective layer 402 more than one or more other wavelengths of laser light. The second laser light removes portions of the conductive reflective layer 402 and extends the first separation gap 500 through the conductive reflective layer 402.

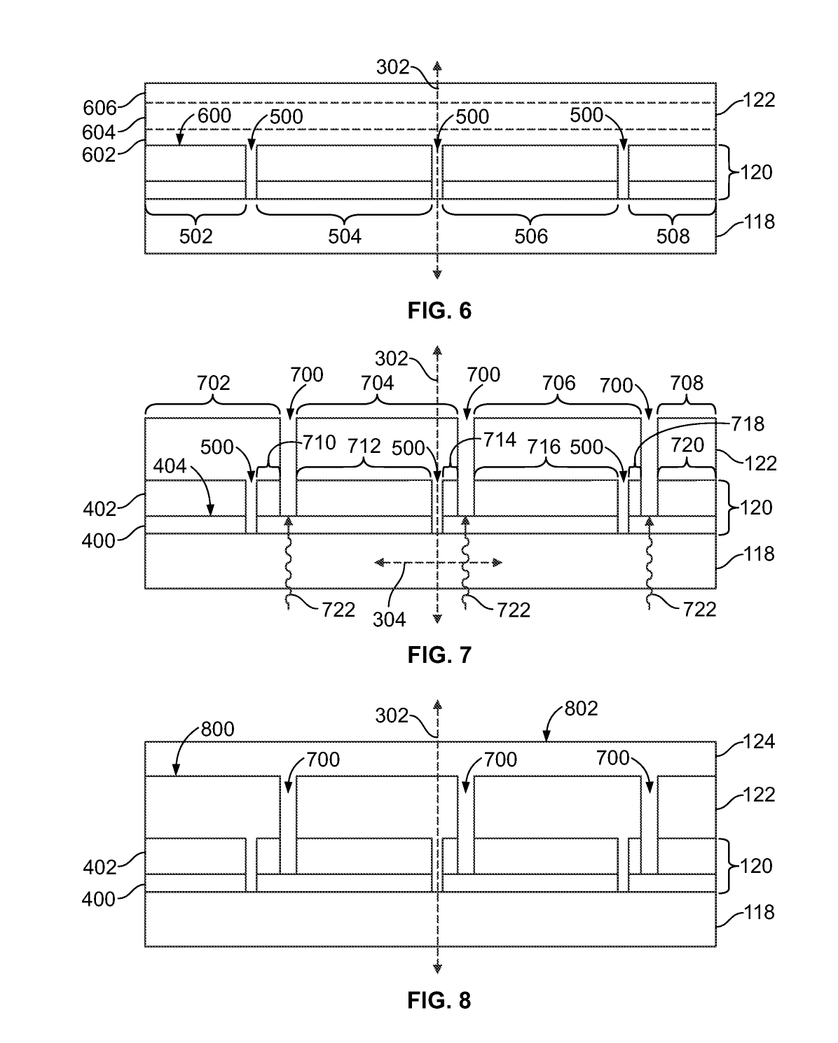

Returning to the discussion of the method 200 shown in FIG. 2, at 208, the semiconductor layer 122 (shown in FIG. 1) is deposited above the lower electrode 120 (shown in FIG. 1). FIG. 6 illustrates the semiconductor layer 122 deposited above the lower electrode 120 and the substrate 118 in accordance with one embodiment.

The semiconductor layer 122 can be deposited onto the lower electrode 120 and the substrate 118 generally along directions that are parallel to the deposition access 302. In one embodiment, the semiconductor layer 122 is deposited onto the lower electrode 120 and is deposited onto substrate 118 within the first separation gaps 500 using a PECVD chamber.

As shown in FIG. 6, the semiconductor layer 122 may be directly deposited onto the lower electrode 120. For example, the semiconductor layer 122 may be deposited onto an upper deposition surface 600 of the lower electrode 120 without any intervening or intermediate layers or films disposed between the semiconductor layer 122 and the lower electrode 120. Alternatively, one or more layers or films, such as a passivation or buffer layer, may be deposited between the lower electrode 120 and the semiconductor layer 122. The semiconductor layer 122 also may be deposited onto the substrate 118 within the first separation gaps 500. For example, the semiconductor layer 122 can be deposited such that the semiconductor layer 122 substantially fills the first separation gaps 500 between the neighboring sections 502, 504, 506, 508 of the lower electrode 120.

The semiconductor layer 122 may be formed from or include a semiconductor material such as silicon, germanium, cadmium, and the like. The semiconductor layer 122 may be one or more of an amorphous layer, a crystalline layer, a microcrystalline layer, or a protocrystalline layer. The semiconductor layer 122 can include multiple layers or films deposited above each other. For example, the semiconductor layer 122 may include an NIP and/or PIN junction of doped and intrinsic semiconductor layers.

In the illustrated embodiment, the semiconductor layer 122 includes an NIP junction of semiconductor films 602, 604, 606. The semiconductor film 602 may be an n-doped semiconductor film that is deposited onto the lower electrode 120 and that is deposited onto the substrate 118 within the first separation gaps 500. The semiconductor film 604 includes an intrinsic semiconductor film that is deposited onto the n-doped semiconductor film 602. The semiconductor film 606 may include a P-doped semiconductor film that is deposited onto the intrinsic semiconductor film 604. While a single NIP junction of semiconductor films 602, 604, 606 is shown, alternatively, multiple NIP or PIN junctions of semiconductor films may be provided as the semiconductor layer 122. For example, two or more tandem semiconductor junctions may be provided as the semiconductor layer 122.

Returning to the discussion of the method 200 shown in FIG. 2, at 210, second separation gaps 700 (shown in FIG. 7) are scribed or etched into the semiconductor layer 122 (shown in FIG. 1) and the lower electrode 120 (shown in FIG. 1). FIG. 7 illustrates the second separation gaps 700 that are scribed into the semiconductor layer 122 and partially into the lower electrode 120 in accordance with one embodiment.

The second separation gaps 700 vertically extend in directions that are parallel to the deposition axis 302. The second separation gaps 700 are laterally offset or spaced apart from the first separation gaps 500. For example, the first and second separation gaps 500, 700 may not be vertically aligned with each other but may be parallel with each other and are separated from each other along the lateral axis 304.

The second separation gaps 700 vertically extend partially through the lower electrode 120 and completely through the semiconductor layer 122 in the illustrated embodiment. For example, the second separation gaps 700 may extend in directions along or parallel to the deposition axis 302 from the upper deposition surface 404 of the conductive light transmissive layer 400 of the lower electrode 120, through a remainder of the lower electrode 120 that includes the entirety of the conductive reflective layer 402 of the lower electrode 120, and through the semiconductor layer 122. The second separation gaps 700 spatially and electrically separate the semiconductor layer 122 into neighboring sections 702, 704, 706, 708. For example, the second separation gaps 700 separate the sections 702, 704 from each other in directions that are parallel to the lateral axis 304, the sections 704, 706 from each other in directions that are parallel to the lateral axis 304, and the sections 706, 708 from each other in directions that are parallel to the lateral axis 304.

In the illustrated embodiment, the second separation gaps 700 spatially and electrically separate the conductive reflective layer 402 into neighboring sections 710, 712, 714, 716, 718, 720. For example, the second separation gaps 700 separate the sections 710, 712 from each other in directions that are parallel to the lateral axis 304, the sections 714, 716 from each other in directions that are parallel to the lateral axis 304, and the sections 718, 720 from each other in direction that are parallel to the lateral axis 304. Also as shown in FIG. 7, the first separation gaps 400 electrically and spatially separate the sections 712, 714 from each other and the sections 716, 718 from each other in directions that are parallel to the lateral axis 304.

Alternatively, the second separation gaps 700 may vertically extend into the conductive light transmissive layer 400. For example, the second separation gaps 700 may partially extend into the conductive light transmissive layer 400 beneath the upper deposition surface 404 in directions that are parallel to the deposition axis 302.

The conductive light transmissive layer 400 laterally extends through the second separation gaps 700 in directions that are parallel to the lateral axis 302 such that the conductive light transmissive layers 400 provide electrically conductive pathways across or through the second separation gaps 700. For example, the conductive light transmissive layer 400 may laterally extend below the second separation gaps 700. The conductive light transmissive layer 400 may be electrically coupled with the sections 710, 712, 714, 716, 718, 720 that are separated from each other by the second separation gaps 700. The conductive light transmissive layer 400 may electrically couple the sections 710, 712 with each other, the sections 714, 716 with each other, and the sections 718, 720 with each other.

In one embodiment, similar to the formation of the first separation gaps 500 (shown in FIG. 5), the second separation gaps 700 may be formed by exposing the semiconductor layer 122 and the conductive layer reflective layer 402 to one or more focused beams of energy, such as one or more laser lights. The focused beams of energy that are used to form the second separation gaps 700 may be directed into the lower electrode 120 and the semiconductor layer 122 through the substrate 118. For example, the laser light passes through the substrate 118 and the conductive light transmissive layer 400 before being absorbed by and removing some or all of the conductive reflective layer 402 and the semiconductor layer 122.

The laser light used to etch the second separation gaps 700 may have one or more wavelengths that differ from the wavelength or wavelengths of the laser light 510 (shown in FIG. 5) used to form the first separation gaps 500. The wavelengths of the laser light used to form the second separation gaps 700 may be based on the materials from which the conductive light transmissive layer 400, the conductive reflective layer 402, and/or the semiconductor layer 122 are formed. For example, the second separation gaps 700 may be formed by exposing the lower electrode 120 to a third laser light 722 having a third wavelength that is absorbed by the conductive reflective layer 402 more than by the conductive light transmissive layer 400 and/or the substrate 118. As a result, the third laser light 722 may pass through the substrate 118 and the conductive light transmissive layer 400 but be absorbed by and remove the conductive reflective layer 402 to form the second separation gaps 700. In one embodiment, the third laser light 722 has a wavelength that also is absorbed by and removes the semiconductor layer 122. Alternatively, a fourth laser light may be directed into the semiconductor layer 122 through the substrate 118 that is absorbed by and removes portions of the semiconductor layer 122 to form the second separation gaps 700 through the semiconductor layer 122. The fourth laser light may have a wavelength that causes the fourth laser light to pass through the conductive light transmissive layer 400 without etching or removing the conductive light transmissive layer 400.

In one embodiment, the fourth laser light may have a wavelength that causes the fourth laser light to be fully absorbed by the conductive light transmissive layer 400 such that none of the fourth laser light reaches the semiconductor layer 122. The fourth laser light may explosively eject a portion the conductive light transmissive layer 400 such that a portion of the semiconductor layer 122 disposed above the conductive light transmissive layer 400 is ejected or removed at the same time that the conductive light transmissive layer 400 is removed.

Returning to the discussion of the method 200 shown in FIG. 2, at 212, the upper electrode 124 (shown in FIG. 1) is deposited above the semiconductor layer 122 (shown in FIG. 1). FIG. 8 illustrates the upper electrode 124 deposited above the semiconductor layer 122 and the lower electrode 120 in accordance with one embodiment. The upper electrode 124 may be deposited onto an upper deposition surface 800 of the semiconductor layer 122. The upper electrode 124 may be directly deposited onto the semiconductor layer 122 such that the upper electrode 124 abuts the semiconductor layer 122. Alternatively, one or more intervening or intermediate layers or films may be provided between the semiconductor layer 122 and the upper electrode 124.

The upper electrode layer 124 is deposited in directions that generally parallel to the deposition access 302. As shown in FIG. 8, the upper electrode 124 may be deposited such that portions of the upper electrode 124 extend into the second separation gaps 700. The upper electrode 124 may be deposited into the second separation gaps 700 such that the upper electrode 124 substantially fills the second separation gaps 700. The upper electrode 124 can extend from above semiconductor layer 122 downward through the second separation gaps 700 along the deposition axis 302 and be electrically coupled with the lower electrode 120. For example, the upper electrode 124 may abut the conductive reflective electrode layer 402 and the conductive light transmissive layer 400 of the lower electrode 120 within the second separation gaps 700.

The upper electrode 124 includes or is formed from conductive material. The upper electrode 124 may be formed from a conductive, light transmissive material such as ITO, AZO, or another conductive light transmissive material. The upper electrode 124 permits light to pass through the upper electrode 124 such that incident light is able to pass through an upper light receiving surface 802 of the upper electrode 124, pass through the upper electrode 124, and enter into the semiconductor layer 122. As described above, the light may be absorbed by the semiconductor layer 122 to generate an electric current.

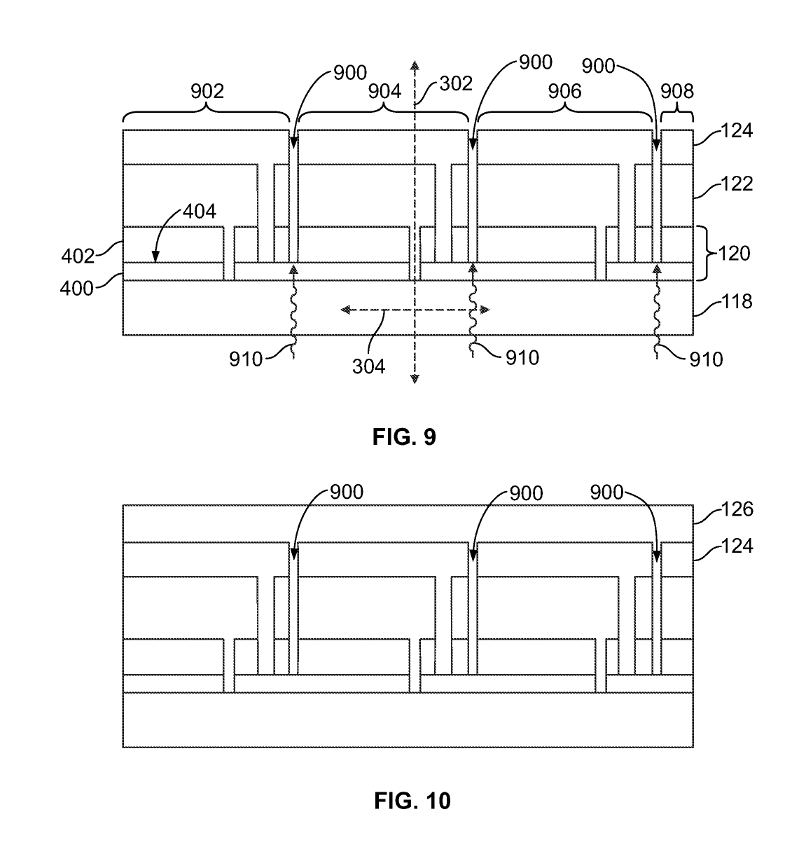

Returning the discussion of the method 200 shown in FIG. 2, at 214, third separation gaps 900 (shown in FIG. 9) are scribed or etched into the upper electrode 124 (shown in FIG. 1). FIG. 9 illustrates the third separation gaps 900 that extend through the upper electrode 124 in accordance with one embodiment. The third separations gaps 900 partially extend through the lower electrode 120, extend through the entirety of the semiconductor layer 122, and extend through the entirety of the upper electrode 124 in directions along or parallel to the deposition axis 302 in the illustrated embodiment. For example, the third separation gaps 900 may extend from the upper deposition surface 404 of the conductive light transmissive layer 400 of the lower electrode 120, through a remainder of the lower electrode 120 that includes the entirety of the conductive reflective layer 402, and through the entirety of the semiconductor layer 122 and the upper electrode 124.

In the illustrated embodiment, the third separation gaps 900 are formed such that the third separation gaps 900 extend through the lower electrode 120, the semiconductor layer 122, and the upper electrode 124. Alternatively, the third separation gaps 900 may only extend through the entirety of the upper electrode 124 and not extend all the way through, or through the entire thickness, of the semiconductor layer 122 and/or the lower electrode 120.

The third separation gaps 900 divide the upper electrode 124 into neighboring sections 902, 904, 906, 908. For example, the third separation gaps 900 may spatially separate the sections 902, 904, 906, 908 from each other in directions that are parallel to the lateral axis 304. The third separation gaps 900 spatially and electrically separate the sections 902, 904 from each other in directions along or parallel to the lateral axis 304, the sections 904, 906 from each other in directions along or parallel to the lateral axis 304, and the sections 906, 908 from each other in directions along or parallel to the lateral axis 304.

Similar to the first and second first separation gaps 500, 700 (shown in FIGS. 5 and 7), the third separation gaps 900 may be formed by directing focused beams of energy, such as one or more laser lights 910, into the lower electrode 120, the semiconductor layer 122, and the upper electrode 124 through the substrate 118. The laser lights 910 may have different wavelengths that are based on the materials from which the lower electrode 120, the semiconductor layer 122, and/or the upper electrode 124 are formed. For example, a fourth laser light 910 may have a fourth wavelength that is absorbed by the conductive reflective layer 402 more than the conductive light transmissive layer 300 and/or the substrate 118. As a result, the fourth laser light 910 passes through the substrate 118 and the conductive light transmissive layer 400 and is absorbed by the conductive reflective layer 402 in order to remove a portion of the conductive reflective layer 402.

In the illustrated embodiment, the fourth laser light 910 may be directed into the upper electrode 124 through the substrate 118 (e.g., from the “substrate side”). Alternatively, the fourth laser light 910 may be directed into the upper electrode 124 from the opposite side. For example, the fourth laser light 910 may be directed into the upper electrode 124 from the “film side” of the device 100, or from a location above the upper electrode 124 in the perspective shown in FIG. 9.

The fourth laser light 910 may have a wavelength that results in the fourth laser light 910 being absorbed by the upper electrode 124 more strongly or to a greater degree than by other layers such that the fourth laser light 910 removes the upper electrode 124 but does not remove the other layers, such as the semiconductor layer 122. Alternatively, the fourth laser light 910 may have a wavelength that results in the fourth laser light 910 passing through the upper electrode 124 (e.g., when the fourth laser light 910 is directed into the upper electrode 124 from the film side of the device 100) and does not remove the upper electrode 124. Such a fourth laser light 910 can pass through the upper electrode 124 and be absorbed by the underlying semiconductor layer 122 such that the fourth laser light 910 causes the semiconductor layer 122 to explosively eject or remove the portion of the upper electrode 124 located above the portion of the semiconductor layer 122 that absorbs the fourth laser light 910.

A fifth laser light 910 may have a fifth wavelength that allows the fifth laser light 910 to pass through the substrate 118 and the conductive light transmissive layer 400 and be absorbed by the semiconductor layer 122 in order to remove a portion of the semiconductor layer 122. A sixth laser light 910 may have a sixth wavelength that allows the sixth laser light 910 to pass through the substrate 118 and the conductive light transmissive layer 400 but be absorbed by and remove a portion of the upper electrode 124. These different wavelengths of laser light 910 remove portions of the conductive reflective layer 402, the semiconductor layer 122, and the upper electrode 124 to form the third separation gaps 900. In one embodiment, the laser light 910 may have a single wavelength or one or more of the fourth, fifth, and/or sixth wavelengths may be the same wavelengths.

Returning to the discussion of the method 200 shown in FIG. 2, at 216, the adhesive 126 (shown in FIG. 1) is deposited above the upper electrode 124 (shown in FIG. 1). FIG. 10 illustrates the adhesive 126 deposited above the upper electrode 124 in accordance with one embodiment. The adhesive 126 may be directly deposited onto the upper electrode 124. Alternatively, one or more intervening or intermediate layers may be deposited between the upper electrode 124 and the adhesive 126. The adhesive 126 may be deposited such that the adhesive 126 extends down into the third separation gaps 900. For example, the adhesive 126 may substantially fill the third separation gaps 900. The adhesive 126 may include a material such as a polyvinyl butyral (“PVB”), surlyn, or ethylene-vinyl acetate (“EVA”) copolymer.

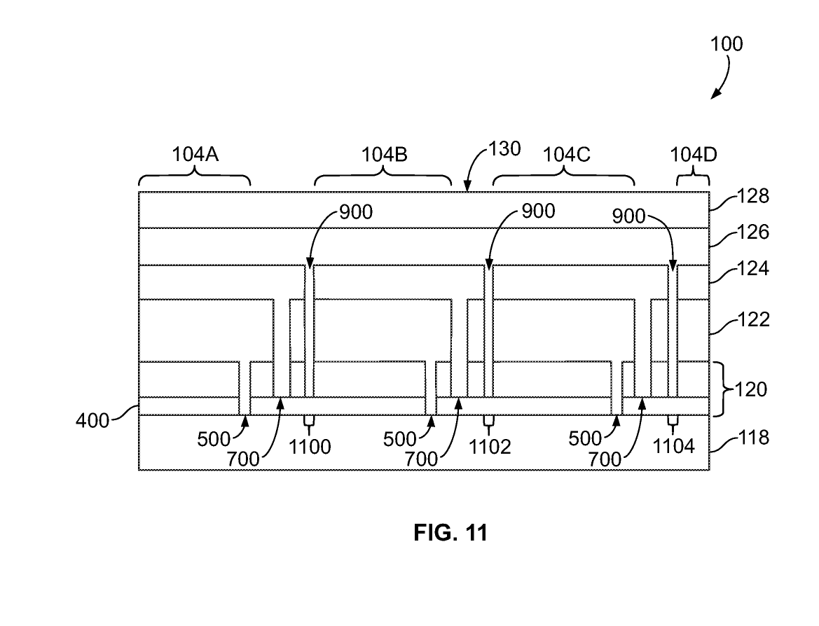

Returning to the discussion of the method 200 shown in FIG. 2, at 218, the cover sheet 128 (shown in FIG. 1) is provided above the adhesive 126 (shown in FIG. 1). FIG. 11 illustrates a cross-sectional view of the photovoltaic device 100 after the cover sheet 128 is provided in accordance with one embodiment. The cover sheet 128 is fixed to the photovoltaic device 100 by the adhesive 126. The cover sheet 128 may include or be formed from a material such as glass in order to protect the photovoltaic device 100 from external elements, such as water, hail, or other physical damage, while permitting light to pass through the cover sheet 128 and enter into the photovoltaic device 100.

As described above, in accordance with one embodiment, three focused beams of energy, such as the laser lights 510, 722, 910 (shown in FIGS. 5, 7, and 9), may be used to scribe various layers of the photovoltaic device 100 in order to define different photovoltaic cells 104. The laser lights 510, 722, 910 scribe the layers of the photovoltaic device 100 such that the photovoltaic cells 104 are electrically connected with each other in series. The laser lights 510, 722, 910 can be directed into the layers of the photovoltaic device 100 through the substrate 118 such that the laser lights 510, 722, 910 vaporize or otherwise remove the semiconductor layer 122 and/or upper electrode 124 from the bottom of the photovoltaic device 100 and permit the semiconductor layer 122 and/or upper electrode 124 to be removed from the photovoltaic device 100 through the film side 130 of the photovoltaic device 100. For example, the laser lights 510, 722, 910 may be directed into the substrate 118 such that the vaporized portions of the lower electrode 120, the semiconductor layer 122, and the upper electrode 124 exit from the photovoltaic device 100 through the film side 130 of the photovoltaic device 100 in the view shown in FIG. 11.

The first, second, and third separation gaps 500, 700, 900 define the photovoltaic cells 104 of the photovoltaic device 100. For ease of discussion, the different photovoltaic cells 104 are labeled 104A, 104B, 104C, 104D in FIG. 11. Two of the photovoltaic cells 104B, 104C are fully shown in FIG. 11 and two photovoltaic cells 104A, 104D are partially shown in FIG. 11. The first separation gaps 500 electrically separate the lower electrodes 120 disposed in each of neighboring photovoltaic cells 104A, 104B, 104C, 104D from each other. For example, the first separation gaps 500 electrically isolate the lower electrode 120 in the photovoltaic cell 104A from the lower electrode 120 in the photovoltaic cell 104B, the lower electrode 120 in the photovoltaic cell 104B from the lower electrode 120 in the photovoltaic cell 104C, and the lower electrode 120 in the photovoltaic cell 104C from the lower electrode 120 in the photovoltaic cell 104D.

In the illustrated embodiment, the second and third separation gaps 700, 900 electrically separate the semiconductor layers 122 disposed in each of neighboring photovoltaic cells 104A, 104B, 104C, 104D from each other. For example, the second and third separation gaps 700, 900 electrically isolate the semiconductor layer 122 in the photovoltaic cell 104A from the semiconductor layer 122 in the photovoltaic cell 104B, the semiconductor layer 122 in the photovoltaic cell 104B from the semiconductor layer 122 in the photovoltaic cell 104C, and the semiconductor layer 122 in the photovoltaic cell 104C from the semiconductor layer 122 in the photovoltaic cell 104D.

As shown in FIG. 11, the portions of the upper electrode 124 that are disposed in the second separation gaps 700 provide a conductive pathway for the upper electrode 124 in one photovoltaic cell 104A, 104B, 104C, 104D to be electrically coupled with the lower electrode 120 with a neighboring photovoltaic cell 104A, 104B, 104C, 104D. This conductive pathway electrically couples neighboring photovoltaic cells 104A, 104B, 104C, 104D in series with each other. For example, the portion of the upper electrode 124 that is in the second separation gap 700 between the photovoltaic cells 104A, 104B electrically couples the upper electrode 124 in the photovoltaic cell 104A with the lower electrode 120 in the photovoltaic cell 104B. The portion of the upper electrode 124 that is in the second separation gap 700 between the photovoltaic cells 104B, 104C electrically couples the upper electrode 124 in the photovoltaic cell 104B with the lower electrode 120 in the photovoltaic cell 104C. The portion of the upper electrode 124 that is in the second separation gap 700 between the photovoltaic cells 104C, 104D electrically couples the upper electrode 124 in the photovoltaic cell 104C with the lower electrode 120 in the photovoltaic cell 104D.

The third separation gaps 900 electrically separate the upper electrodes 124 disposed in each of neighboring photovoltaic cells 104A, 104B, 104C, 104D from each other. For example, the third separation gaps 900 electrically isolate the upper electrode 124 in the photovoltaic cell 104A from the upper electrode 124 in the photovoltaic cell 104B, the upper electrode 124 in the photovoltaic cell 104B from the upper electrode 124 in the photovoltaic cell 104C, and the upper electrode 124 in the photovoltaic cell 104C from the upper electrode 124 in the photovoltaic cell 104D.

As described above, the conductive light transmissive layer 400 laterally extends through or across the third separation gaps 900 to provide lateral conductive pathways through the third separation gaps 900. For example, portions 1100, 1102, 1104 of the conductive light transmissive layer 400 extend through or across the third separation gaps 900 to electrically couple the upper electrode 124 in one photovoltaic cell 104A, 104B, 104C, 104D with the lower electrode 120 in a neighboring photovoltaic cell 104A, 104B, 104C, 104D. In the illustrated embodiment, the portion 1100 of the conductive light transmissive layer 400 electrically couples the upper electrode 124 of the photovoltaic cell 104A with the lower electrode 120 of the photovoltaic cell 104B. The portion 1102 of the conductive light transmissive layer 400 electrically couples the upper electrode 124 of the photovoltaic cell 104B with the lower electrode 120 of the photovoltaic cell 104C. The portion 1104 of the conductive light transmissive layer 400 electrically couples the upper electrode 124 of the photovoltaic cell 104C with the lower electrode 120 of the photovoltaic cell 104C.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and merely are example embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A photovoltaic device comprising first and second photovoltaic cells, each of the first and second photovoltaic cells comprising:
a substrate;
a lower electrode disposed above the substrate along a deposition axis, the lower electrode including a conductive light transmissive layer;
one or more semiconductor layers disposed above the substrate along the deposition axis; and
an upper electrode disposed above the one or more semiconductor layers along the deposition axis, the one or more semiconductor layers converting incident light into an electric current, wherein the first and second photovoltaic cells are separated by first and second separation gaps, the first separation gap extending along the deposition axis through the lower electrode from the substrate, the second separation gap extending from a deposition surface of the light transmissive layer of the lower electrode and through a remainder of the lower electrode and the one or more semiconductor layers along the deposition axis.

2. The photovoltaic device of claim 1, wherein the substrate continuously extends along a lateral axis below the lower electrodes of the first and second photovoltaic cells.

3. The photovoltaic device of claim 1, wherein the first and second photovoltaic cells are separated by a third separation gap extending along the deposition axis from the deposition surface of the light transmissive layer of the lower electrode and through a remainder of the lower electrode, the one or more semiconductor layers, and the upper electrode.

4. The photovoltaic device of claim 1, wherein the light transmissive layer of the lower electrode extends along a lateral axis through the second separation gap to provide an electrically conductive pathway between the first and second photovoltaic cells through the second separation gap.

5. The photovoltaic device of claim 1, wherein the upper electrode extends along the deposition axis to the light transmissive layer of the lower electrode in the second separation gap to electrically couple the portion of the upper electrode of the first photovoltaic cell to the portion of the lower electrode of the second photovoltaic cell.

6. The photovoltaic device of claim 1, wherein the lower electrode includes a conductive reflective layer disposed between the light transmissive layer and the one or more semiconductor layers.

7. The photovoltaic device of claim 1, wherein the one or more semiconductor layers include an NIP junction of semiconductor films.

8. The photovoltaic device of claim 1, wherein the substrate is a light transmissive substrate.

9. The photovoltaic device of claim 1, wherein the one or more semiconductor layers extends along the deposition axis to the substrate in the first separation gap.

10. The photovoltaic device of claim 1, wherein the upper electrode extends along the deposition axis to the light transmissive layer of the lower electrode in the second separation gap.

11. A photovoltaic device comprising first and second photovoltaic cells, the photovoltaic device comprising:
a substrate;
a conductive light transmissive upper electrode including a light receiving side that is disposed opposite of the substrate along a deposition axis;
a conductive lower electrode disposed between the substrate and the upper electrode along the deposition axis, the lower electrode including a conductive light transmissive layer;
one or more semiconductor layers disposed between the lower electrode and the upper electrode along the deposition axis, the one or more semiconductor layers converting light that is received through the light receiving side of the upper electrode into an electric current in the first and second photovoltaic cells;
a first separation gap extending along the deposition axis through the lower electrode from the substrate to the semiconductor layers, the first separation gap electrically separating portions of the lower electrode in the first and second photovoltaic cells along a lateral axis; and
a second separation gap extending along the deposition axis from the conductive light transmissive layer of the lower electrode and through the one or more semiconductor layers to the upper electrode, the second separation gap separating portions of the one or more semiconductor layers in the first and second photovoltaic cells along the lateral axis.

12. The photovoltaic device of claim 11, wherein the light transmissive layer of the lower electrode extends from the first photovoltaic cell to the second photovoltaic cell through the second separation gap to provide an electrically conductive pathway through the second separation gap.

13. The photovoltaic device of claim 11, wherein the upper electrode extends to the light transmissive layer of the lower electrode in the second separation gap to electrically couple the portion of the upper electrode of the first photovoltaic cell to the portion of the lower electrode of the second photovoltaic cell.

14. The photovoltaic device of claim 11, further comprising a third separation gap extending from the light transmissive layer of the lower electrode through the one or more semiconductor layers and the upper electrode, the third separation gap separating the portions of the one or more semiconductor layers in the first and second photovoltaic cells and separating portions of the upper electrode in the first and second photovoltaic cells.

15. The photovoltaic device of claim 11, wherein the lower electrode includes a conductive reflective layer with the light transmissive layer of the lower electrode disposed between the substrate and the reflective layer.

16. The photovoltaic device of claim 11, wherein the one or more semiconductor layers includes an NIP junction of semiconductor films, the NIP junction including an n-doped semiconductor film disposed between the lower electrode and the upper electrode, an intrinsic semiconductor film disposed between the n-doped semiconductor film and the upper electrode, and a p-doped semiconductor film disposed between the intrinsic semiconductor film and the upper electrode.

17. The photovoltaic device of claim 11, wherein the substrate is a light transmissive substrate.

18. The photovoltaic device of claim 11, wherein the one or more semiconductor layers extends to the substrate in the first separation gap.

19. The photovoltaic device of claim 11, wherein the upper electrode is disposed in and coupled with the light transmissive layer of the lower electrode in the second separation gap to electrically couple the portion of the upper electrode in the first photovoltaic cell with the portion of the lower electrode in the lower electrode.

20. The photovoltaic device of claim 11, wherein the deposition and lateral axes are perpendicular to each other.

21. A method for scribing a photovoltaic device having first and second photovoltaic cells, the method comprising:
providing a substrate and a conductive lower electrode above the substrate along a deposition axis of the photovoltaic device, the lower electrode including a conductive light transmissive layer;
directing a first laser light through the substrate to etch a first separation gap in the lower electrode, the first separation gap extending along a lateral axis to electrically separate portions of the lower electrode in the first and second photovoltaic cells;
depositing one or more semiconductor layers above the lower electrode along the deposition axis;
directing a second laser light through the substrate to etch a second separation gap in the lower electrode and the one or more semiconductor layers, the second separation gap extending along the lateral axis to separate portions of the one or more semiconductor layers in the first and second photovoltaic cells; and
depositing a conductive light transmissive upper electrode above the one or more semiconductor layers along the deposition axis, wherein the one or more semiconductor layers convert incident light between the upper and lower electrodes and convert the light into an electric current.

22. The method of claim 21, wherein the first separation gap extends through the lower electrode along the deposition axis from the substrate to a deposition surface of the lower electrode with the one or more semiconductor layers deposited on the deposition surface of the lower electrode.

23. The method of claim 21, wherein the second separation gap partially extends through the lower electrode and through the one or more semiconductor layers along the deposition axis from the light transmissive layer of the lower electrode to a deposition surface of the one or more semiconductor layers with the upper electrode deposited on the deposition surface of the one or more semiconductor layers.

24. The method of claim 21, further comprising directing a third laser light through the substrate to etch a third separation gap in the upper electrode, the third separation gap extending along the lateral axis to electrically separate portions of the upper electrode in the first and second photovoltaic cells.

25. The method of claim 24, wherein the third separation gap partially extends through the lower electrode and through the one or more semiconductor layers and the upper electrode along the deposition axis from the light transmissive layer of the lower electrode to an upper surface of the upper electrode.

26. The method of claim 21, wherein the light transmissive layer of the lower electrode extends along the lateral axis through the second separation gap to provide an electrically conductive pathway between the first and second photovoltaic cells through the second separation gap.

27. The method of claim 21, wherein the upper electrode extends along the deposition axis to the light transmissive layer of the lower electrode in the second separation gap to electrically couple the portion of the upper electrode of the first photovoltaic cell to the portion of the lower electrode of the second photovoltaic cell.

28. The method of claim 21, wherein the depositing the lower electrode includes depositing a conductive reflective layer above the light transmissive layer along the deposition axis with the light transmissive layer disposed between the substrate and the reflective layer along the deposition axis.

29. The method of claim 21, wherein the depositing the one or more semiconductor layers includes depositing an n-doped semiconductor film above the lower electrode along the deposition axis, depositing an intrinsic semiconductor film above the n-doped semiconductor film along the deposition axis, and depositing a p-doped film above the intrinsic semiconductor film along the deposition axis.

30. The method of claim 21, wherein the substrate is a light transmissive substrate.

31. The method of claim 21, wherein the depositing the one or more semiconductor layers includes depositing the one or more semiconductor layers onto the substrate in the first separation gap.

32. The method of claim 21, wherein the depositing the upper electrode includes depositing the upper electrode onto the light transmissive layer of the lower electrode in the second separation gap.
